(19) United States
(12) Patent Application Publication
(10) Pub. No.: US 2024/0395707 A1
(43) Pub. Date: Nov. 28, 2024

(54) SEMICONDUCTOR DEVICE AND METHOD OF MANUFACTURING THE SAME

(71) Applicant: Kioxia Corporation, Tokyo (JP)

(72) Inventors: Hiroomi NAKAJIMA, Setagaya Tokyo (JP); Go OIKE, Kuwana Mie (JP)

(73) Assignee: Kioxia Corporation, Tokyo (JP)

(21) Appl. No.: 18/657,050

(22) Filed: May 7, 2024

(30) Foreign Application Priority Data
May 22, 2023 (JP) 2023-084186

(51) Int. Cl. H01L 23/528; G11C 16/04; H01L 23/522; H10B 41/10; H10B 41/27; H10B 41/35; H10B 43/10; H10B 43/27; H10B 43/35

(52) U.S. Cl. CPC H01L 23/5283; G11C 16/0483; H01L 23/5226; H10B 41/10; H10B 41/27; H10B 41/35; H10B 43/10; H10B 43/27; H10B 43/35

(57) ABSTRACT

In one embodiment, a semiconductor device includes a first substrate. The device further includes a memory cell array including a plurality of first electrode layers that are provided above the first substrate, and are spaced from each other in a first direction, a columnar portion that is provided in the plurality of first electrode layers, extends in the first direction, and includes a charge storage layer and a semiconductor layer, and a first metal layer that is provided above the plurality of first electrode layers, and is electrically connected to an end of the semiconductor layer. The device further includes a first plug provided above the first substrate. The device further includes a first interconnect layer provided above the first plug, and electrically connected to the first plug through the first metal layer.

### CROSS REFERENCE TO RELATED APPLICATIONS

This application is based upon and claims the benefit of priority from the prior Japanese Patent Application No. 2023-084186, filed on May 22, 2023, the entire contents of which are incorporated herein by reference.

### FIELD

Embodiments described herein relates to a semiconductor device and a method of manufacturing the same.

### BACKGROUND

When interconnect layers of a three-dimensional semiconductor memory are sequentially formed, a shape of at least one of the interconnect layers may become unfavorable. For example, when a lower interconnect layer including a source line and an upper interconnect layer including a bonding pad are sequentially formed, a shape of the upper interconnect layer may become unfavorable.

### BRIEF DESCRIPTION OF THE DRAWINGS

FIG. 1 is a cross-sectional view illustrating a structure of a semiconductor device of a first embodiment;

FIG. 2 is an enlarged cross-sectional view illustrating the structure of the semiconductor device of the first embodiment;

FIGS. 3 to 6 are cross-sectional views illustrating a method of manufacturing the semiconductor device of the first embodiment;

FIG. 7 is another cross-sectional view illustrating the structure of the semiconductor device of the first embodiment;

FIG. 8 is a plan view illustrating the structure of the semiconductor device of the first embodiment;

FIG. 9 is a cross-sectional view illustrating a structure of a semiconductor device of a comparative example of the first embodiment;

FIG. 10 is a plan view illustrating the structure of the semiconductor device of the comparative example of the first embodiment;

FIGS. 11 to 16 are cross-sectional views illustrating the method of manufacturing the semiconductor device of the first embodiment;

FIG. 17 is a cross-sectional view illustrating a structure of a semiconductor device of a second embodiment;

FIG. 18 is a plan view illustrating the structure of the semiconductor device of the second embodiment;

FIGS. 19 to 24 are cross-sectional views illustrating a method of manufacturing the semiconductor device of the second embodiment;

FIG. 25 is a cross-sectional view illustrating a structure of a semiconductor device of a third embodiment;

FIG. 26 is a plan view illustrating the structure of the semiconductor device of the third embodiment;

FIG. 27 is a cross-sectional view illustrating a structure of a semiconductor device of a fourth embodiment;

FIG. 28 is a timing chart illustrating an operation example of the semiconductor device of the fourth embodiment; and

FIG. 29 is a graph for explaining an operation of the semiconductor device of the fourth embodiment.

### DETAILED DESCRIPTION

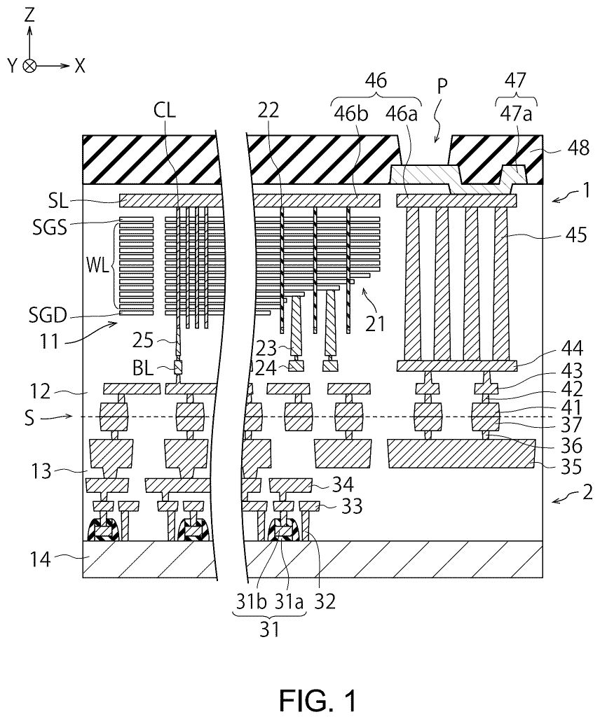

Embodiments will now be explained with reference to the accompanying drawings. In FIGS. 1 to 29, the same reference sign is used to refer to the same components and a redundant explanation is omitted.

In one embodiment, a semiconductor device includes a first substrate. The device further includes a memory cell array including a plurality of first electrode layers that are provided above the first substrate, and are spaced from each other in a first direction, a columnar portion that is provided in the plurality of first electrode layers, extends in the first direction, and includes a charge storage layer and a semiconductor layer, and a first metal layer that is provided above the plurality of first electrode layers, and is electrically connected to an end of the semiconductor layer. The device further includes a first plug provided above the first substrate. The device further includes a first interconnect layer provided above the first plug, and electrically connected to the first plug through the first metal layer.

### First Embodiment

FIG. 1 is a cross-sectional view illustrating a structure of a semiconductor device of a first embodiment.

The semiconductor device of the present embodiment includes, for example, a three-dimensional semiconductor memory. The semiconductor device of the present embodiment is manufactured by bonding an array wafer including an array chip 1 to a circuit wafer including a circuit chip 2 as described later.

The array chip 1 includes a memory cell array 11 including a plurality of memory cells and an inter layer dielectric 12 under the memory cell array 11. The inter layer dielectric 12 is, for example, a stacked film including an SiO₂ film (a silicon oxide film) and another insulator.

The circuit chip 2 is provided under the array chip 1. FIG. 1 illustrates a bonding face S between the array chip 1 and the circuit chip 2. The circuit chip 2 includes an inter layer dielectric 13 under the inter layer dielectric 12 and a substrate 14 under the inter layer dielectric 13. The inter layer dielectric 13 is, for example, a stacked film including an SiO₂ film and another insulator. The substrate 14 is, for example, a semiconductor substrate such as an Si (silicon) substrate. The substrate 14 is an example of the first substrate.

FIG. 1 illustrates an X direction and a Y direction parallel with a surface of the substrate 14 and perpendicular to each other and a Z direction perpendicular to the surface of the substrate 14. The X direction, the Y direction, and the Z direction intersect one another. Herein, a +Z direction is treated as an upward direction and a −Z direction is treated as a downward direction. The −Z direction may be or may not be in alignment with a direction of gravitational force. The Z direction is an example of a first direction.

The array chip 1 includes, as a plurality of electrode layers in the memory cell array 11, a plurality of word lines WL, a source-side selective line SGS, and a drain-side selective line SGD. The source-side selective line SGS is disposed above the word lines WL and the drain-side selective line SGD is disposed below the word lines WL. The word lines WL, the source-side selective line SGS, and the drain-side selective line SGD are examples of a first electrode layer. The memory cell array 11 includes a plurality of columnar portions CL penetrating the word lines WL, the source-side selective line SGS, and the drain-side selective line SGD. The columnar portions CL extend in the Z direction.

FIG. 1 illustrates a stepped structure 21 in the memory cell array 11 and a plurality of beams 22 provided in the stepped structure 21. The beams 22 extend in the Z direction. The word lines WL are each electrically connected to a word interconnect layer 24 through a contact plug 23. The columnar portions CL are each electrically connected to a bit line BL through a via plug 25 and electrically connected to a source line SL. The source line SL is provided above the source-side selective line SGS and the bit line BL is provided below the drain-side selective line SGD. The source line SL is provided on the columnar portions CL to be in contact with the columnar portions CL. The source line SL is a part of the memory cell array 11. The source line SL will be described later in further detail.

Although only the uppermost one of the electrode layers serves as the source-side selective line SGS in FIG. 1, a plurality of the electrode layers on an uppermost side may serve as source-side selective lines SGS. Likewise, although only the lowermost one of the electrode layers serves as the drain-side selective line SGD in FIG. 1, a plurality of the electrode layers on a lowermost side may serve as drain-side selective lines SGD.

The circuit chip 2 further includes a plurality of transistors 31, a plurality of contact plugs 32, an interconnect layer 33, an interconnect layer 34, an interconnect layer 35, a plurality of via plugs 36, and a plurality of metal pads 37.

The transistors 31 each include a gate insulator 31a and a gate electrode 31b provided on the substrate 14 in sequence and a source region and a drain region (not illustrated) provided in the substrate 14. The contact plugs 32 are each provided on the gate electrode 31b of corresponding one of the transistors 31, the source region, or the drain region. The interconnect layer 33 is provided on the contact plugs 32 and includes a plurality of interconnects. The interconnect layer 34 is provided on the interconnect layer 33 and includes a plurality of interconnects. The interconnect layer 35 is provided on the interconnect layer 34 and includes a plurality of interconnects. The via plugs 36 are provided on the interconnect layer 35. The metal pads 37 are provided on the via plugs 36. The metal pads 37 are, for example, metal layers including a Cu (copper) layer. The circuit chip 2 functions as a circuit that controls an operation of the array chip 1. This circuit includes the transistors 31 and the like and is electrically connected to the metal pads 37.

The array chip 1 further includes a plurality of metal pads 41, plurality of via plugs 42, an interconnect layer 43, an interconnect layer 44, a plurality of via plugs 45, an interconnect layer 46, an interconnect layer 47, and a passivation insulator 48. The via plugs 45 are examples of a first plug. The interconnect layer 46 is an example of a first metal layer. A portion of the interconnect layer 47 is an example of a first interconnect layer.

The metal pads 41 are provided on the metal pads 37. The metal pads 41 are, for example, metal layers including a Cu layer. The above-described circuit is electrically connected to the memory cell array 11 through the metal pads 37 and 41 and the like and controls an operation of the memory cell array 11 through the metal pads 37 and 41 and the like. The via plugs 42 are provided on the metal pads 41. The interconnect layer 43 is provided on the via plugs 42 and includes a plurality of interconnects. The interconnect layer 44 is provided on the interconnect layer 43 and includes a plurality of interconnects. The above-described bit line BL is included in the interconnect layer 44. The via plugs 45 are provided on the interconnect layer 44. The via plugs 45 are, for example, metal plugs including a metal layer.

The interconnect layer 46 is disposed on the via plugs 45 and disposed above the source-side selective line SGS. The interconnect layer 46 is, for example, a metal layer including a W (tungsten) layer. The interconnect layer 46 includes a plurality of interconnects such as interconnects 46a and 46b. The interconnect 46a is provided on the via plugs 45 to be in contact with the via plugs 45. The interconnect 46b is provided above the memory cell array 11. The interconnect 46b serves as the above-described source line SL. The interconnect 46b is an example of a first portion. The interconnect 46a is an example of a second portion.

The interconnect layer 47 is disposed on the inter layer dielectric 12 and disposed above the interconnect layer 46 with the inter layer dielectric 12 in between. The interconnect layer 47 is, for example, a metal layer including an Al (aluminum) layer. The interconnect layer 47 includes a plurality of interconnects such as an interconnect 47a. The interconnect 47a is provided on the interconnect 46a to be in contact with the interconnect 46a. A portion of the interconnect 47a functions as an external connection pad (a bonding pad) of the semiconductor device of the present embodiment. A portion of the interconnect 47a is an example of a third portion.

The passivation insulator 48 is provided on the interconnect layer 47 and the inter layer dielectric 12 and has an opening P in which an upper face of the interconnect 47a is exposed. A portion of the interconnect 47a exposed in the opening P functions as the above-described external connection pad. The interconnect 47a is connectable to a mounting substrate or another device through the opening P with a bonding wire, solder ball, metal bump, or the like. The passivation insulator 48 is, for example, a stacked insulator including an SiO₂ film and an SiN film (a silicon nitride film).

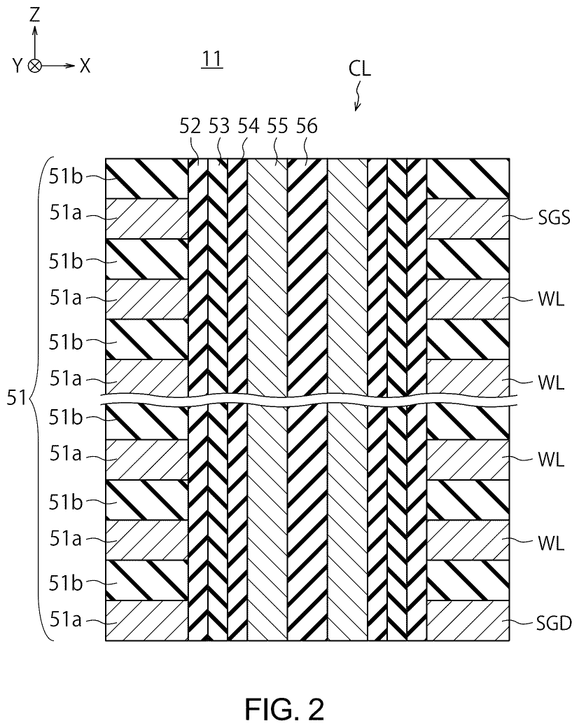

FIG. 2 is an enlarged cross-sectional view illustrating the structure of the semiconductor device of the first embodiment.

FIG. 2 illustrates the memory cell array 11 illustrated in FIG. 1. The memory cell array 11 includes a stacked film 51 including a plurality of electrode layers 51a and a plurality of insulators 51b alternately stacked in the Z direction. The electrode layers 51a are spaced from one another in the Z direction. The electrode layers 51a individually function as, for example, the above-described word lines WL, source-side selective line SGS, or drain-side selective line SGD. In FIG. 2, the uppermost electrode layer 51a serves as the source-side selective line SGS, the lowermost electrode layer 51a serves as the drain-side selective line SGD, and the other electrode layers 51a serve as the word lines WL. The electrode layers 51a are examples of the first electrode layer. The electrode layers 51a are, for example, metal layers including a W layer. The insulators 51b are, for example, SiO₂ films.

FIG. 2 further illustrates one of the plurality of columnar portions CL illustrated in FIG. 1. The columnar portions CL are provided in the stacked film 51 and have a columnar shape extending in the Z direction. The columnar portions CL each include a block insulator 52 provided on a side face of the stacked film 51, a charge storage layer 53 provided on a side face of the block insulator 52, a tunnel insulator 54 provided on a side face of the charge storage layer 53, a channel semiconductor layer 55 provided on a side face of the tunnel insulator 54, and a core insulator 56 provided on a side face of the channel semiconductor layer 55. The columnar portions CL each form cell transistors (memory cells) in combination with the word lines WL, form a source-side selective transistor in combination with the source-side selective line SGS, and form a drain-side selective transistor in combination with the drain-side selective line SGD.

The block insulator 52 is, for example, an SiO₂ film. The charge storage layer 53 is, for example, an insulator such as an SiN film. The charge storage layer 53 may be a semiconductor layer such as a polysilicon layer. The charge storage layer 53 can store a signal charge of the three-dimensional semiconductor memory. The tunnel insulator 54 is, for example, an SiO₂ film or an SiON film (a silicon oxynitride film). The channel semiconductor layer 55 is, for example, a polysilicon layer. The channel semiconductor layer 55 functions as a channel of the three-dimensional semiconductor memory. The channel semiconductor layer 55 is an example of a semiconductor layer. The core insulator 56 is, for example, an SiO₂ film.

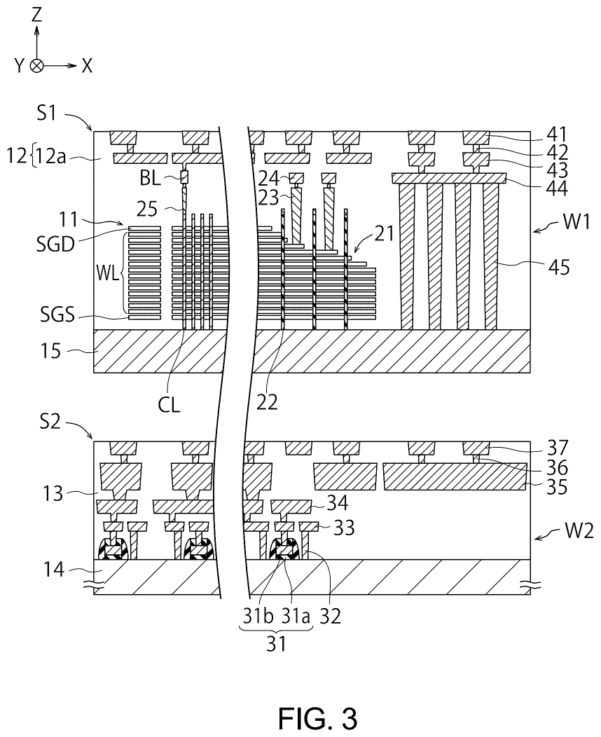

FIGS. 3 to 6 are cross-sectional views illustrating a method of manufacturing the semiconductor device of the first embodiment.

FIG. 3 illustrates an array wafer W1 including a plurality of array chips 1 and a circuit wafer W2 including a plurality of circuit chips 2. An orientation of the array wafer W1 in FIG. 3 is opposite to an orientation of the array chip 1 in FIG. 1. In the present embodiment, the semiconductor device is manufactured by bonding the array wafer W1 and the circuit wafer W2 together. FIG. 3 illustrates the array wafer W1 having an orientation not inverted for bonding, whereas FIG. 1 illustrates the array chip 1 having an orientation inverted for bonding and bonded and diced.

FIG. 3 further illustrates an upper face S1 of the array wafer W1 and an upper face S2 of the circuit wafer W2. The array wafer W1 includes a substrate 15 below the memory cell array 11. The substrate 15 is, for example, a semiconductor substrate such as an Si substrate. The substrate 15 is an example of a second substrate.

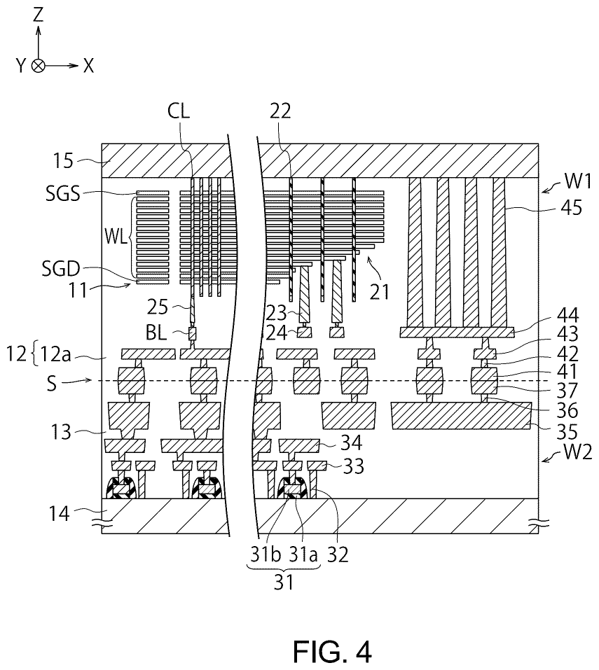

In the present embodiment, first, the memory cell array 11, an inter layer dielectric 12a (=a portion of the inter layer dielectric 12), the stepped structure 21, the metal pads 41, the via plugs 45, and the like are formed on the substrate 15 of the array wafer W1 and the inter layer dielectric 13, the transistors 31, the metal pads 37, and the like are formed on the substrate 14 of the circuit wafer W2 as illustrated in FIG. 3. Next, the array wafer W1 and the circuit wafer W2 are bonded together by a mechanical pressure with the upper face S1 facing the upper face S2 as illustrated in FIG. 4. This causes the inter layer dielectric 12a to be bonded to the inter layer dielectric 13. Next, the array wafer W1 and the circuit wafer W2 are annealed. This causes the metal pads 41 to be joined to the metal pads 37. The substrate 15 and the substrate 14 are bonded together with the inter layer dielectrics 12a and 13 sandwiched in between in this manner, causing the memory cell array 11, the via plugs 45, and the like to be formed (disposed) above the substrate 14.

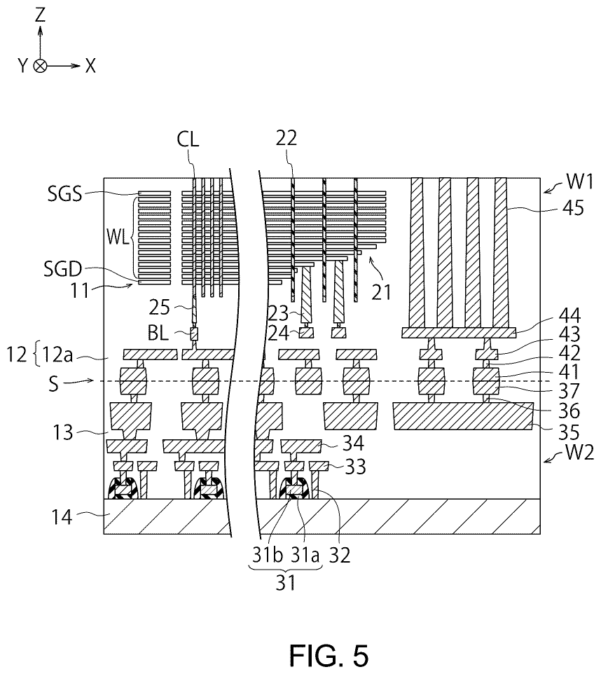

Next, the substrate 15 is removed by CMP (Chemical Mechanical Polishing) or wet etching and the substrate 14 is thinned by CMP or wet etching (FIG. 5). This causes the inter layer dielectric 12a, the columnar portions CL, the beams 22, the via plugs 45, and the like to be exposed.

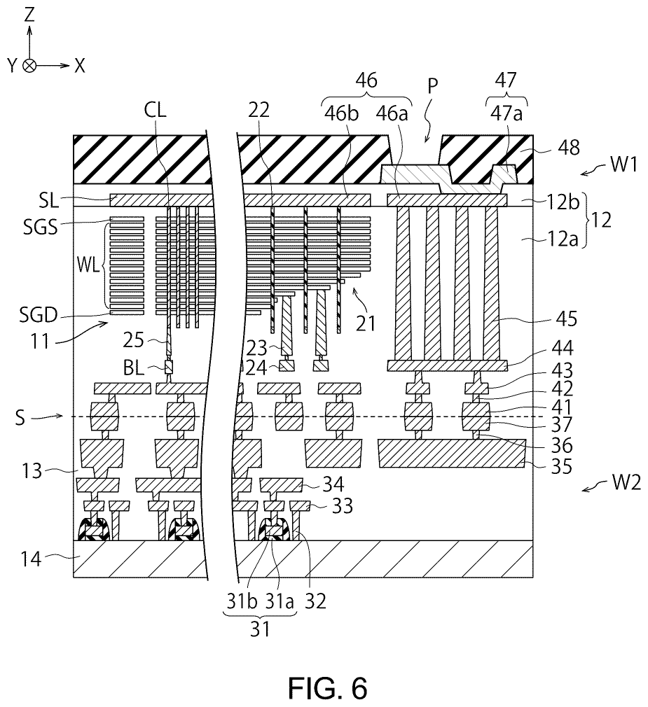

Next, the interconnect layer 46 is formed on the inter layer dielectric 12a, the columnar portions CL, the beams 22, and the via plugs 45 and an inter layer dielectric 12b (=the remnant of the inter layer dielectric 12) is formed on the inter layer dielectric 12a with the interconnect layer 46 in between (FIG. 6). The inter layer dielectric 12b is an example of a first insulator. The interconnect layer 46 is formed to include the interconnect 46a and the interconnect 46b (the source line SL). The interconnect 46a is formed on the via plugs 45 to be in contact with the via plugs 45. The interconnect 46b is formed above the memory cell array 11.

Next, the interconnect layer 47 is formed on the inter layer dielectric 12b (FIG. 6). As a result, the interconnect layer 47 is formed above the interconnect layer 46 with the inter layer dielectric 12b in between, causing the inter layer dielectric 12b to lie between the interconnect layer 46 and the interconnect layer 47. The interconnect layer 47 is formed on the inter layer dielectric 12b after an opening where the interconnect 46a is to be exposed is formed in the inter layer dielectric 12b. As a result, the interconnect layer 47 is formed to include the interconnect 47a. The interconnect 47a is formed on the interconnect 46a to be in contact with the interconnect 46a.

Next, the passivation insulator 48 is formed on the inter layer dielectric 12b and the interconnect layer 47 and the opening P is formed in the passivation insulator 48 (FIG. 6). As a result, the interconnect 47a is exposed in the opening P.

Subsequently, the array wafer W1 and the circuit wafer W2 are cut into a plurality of chips. The semiconductor device illustrated in FIG. 1 is manufactured in this manner.

Although FIG. 1 illustrates a boundary face between the inter layer dielectric 12 and the inter layer dielectric 13 and a boundary face between the metal pads 41 and the metal pads 37, neither of the boundary faces usually becomes observed after the above-described annealing. However, positions where the boundary faces existed are assumable by detecting, for example, inclinations of side faces of the metal pads 41 and side faces of the metal pads 37 or a positional offset between the side faces of the metal pads 41 and the side faces of the metal pads 37.

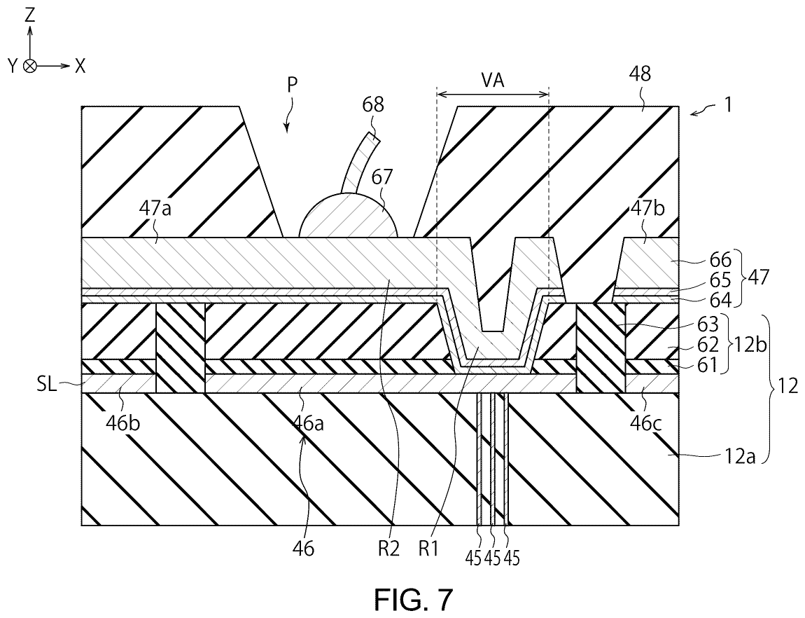

FIG. 7 is another cross-sectional view illustrating the structure of the semiconductor device of the first embodiment.

FIG. 7 illustrates a part of FIG. 1 on a larger scale. FIG. 7 illustrates the above-described inter layer dielectric 12, via plugs 45, interconnect layer 46, interconnect layer 47, and passivation insulator 48. The inter layer dielectric 12 includes the above-described inter layer dielectrics 12a and 12b.

The interconnect layer 46 includes the interconnect 46a, the interconnect 46b (the source line SL), and an interconnect 46c. The interconnect 46a is formed on the inter layer dielectric 12a and the via plugs 45. The interconnect 46b is formed on the inter layer dielectric 12a and disposed above the memory cell array 11 (FIG. 1). The interconnect 46c is formed on the inter layer dielectric 12a. The interconnect layer 46 is, for example, a metal layer including a W layer. The interconnect layer 46 illustrated in FIG. 7 is formed of a metal layer only, and includes no semiconductor layer. Thus, the metal layer included in the interconnect layer 46 is in contact with the metal layers included in the via plugs 45 in FIG. 7. The interconnect 46c may be a portion of the interconnect 46b as in a later-described example.

The inter layer dielectric 12b includes an insulator 61, an insulator 62, and an insulator 63. The insulator 61 is formed on the interconnect layer 46. The insulator 62 is formed on the insulator 61, and formed of an insulating material different in type from an insulating material of the insulator 61. The insulator 63 penetrates the interconnect layer 46, the insulator 61, and the insulator 62 and is formed of an insulating material different in type from the insulating material of the insulator 61 and/or the insulating material of the insulator 62. The interconnect 46a, the interconnect 46b, and the interconnect 46c are separated from one another by the insulator 63.

The interconnect layer 47 includes the interconnect 47a and an interconnect 47b. The interconnect 47a includes a portion R1 and a portion R2. The portion R1 is formed on the interconnect 46a inside the inter layer dielectric 12b. The portion R2 is formed on the inter layer dielectric 12b outside the inter layer dielectric 12b. The portion R1 functions as a via plug. The portion R2 functions as a bonding pad. The portion R1 is an example of a second plug. The portion R2 is an example of the third portion. The interconnect 47b is formed on the inter layer dielectric 12b.

The interconnect layer 47 includes a lower barrier metal layer 64, an upper barrier metal layer 65, and an interconnect material layer 66. The interconnect material layer 66 is a main layer in the interconnect layer 47 and the lower barrier metal layer 64 and the upper barrier metal layer 65 are underlayers for the interconnect material layer 66. The lower barrier metal layer 64 and the upper barrier metal layer 65 are examples of a barrier metal layer. The lower barrier metal layer 64, the upper barrier metal layer 65, and the interconnect material layer 66 are formed in sequence on the inter layer dielectric 12b and the interconnect layer 46. The lower barrier metal layer 64 is, for example, a Ti (titanium) layer. The upper barrier metal layer 65 is, for example, a TiN film (a titanium nitride film). The interconnect material layer 66 is, for example, an Al layer. In FIG. 7, the metal layer (the lower barrier metal layer 64) included in the interconnect layer 47 is in contact with the metal layer included in the interconnect layer 46.

In the present embodiment, the portion R1 and the portion R2 of the interconnect 47a are simultaneously formed of the same interconnect material. Specifically, the portion R1 includes the lower barrier metal layer 64, the upper barrier metal layer 65, and the interconnect material layer 66 and the portion R2 also includes the lower barrier metal layer 64, the upper barrier metal layer 65, and the interconnect material layer 66. In contrast, the portion R1 and the portion R2 of the interconnect 47a in a later-described second embodiment are formed of different interconnect materials in sequence.

The interconnect 47a and the interconnect 47b are separated from each other by the passivation insulator 48 formed in the interconnect layer 47. Further, the passivation insulator 48 is also formed on the portion R1 of the interconnect 47a. FIG. 7 further illustrates a solder 67 and a bonding wire 68 electrically connected to the solder 67. The solder 67 is formed on the portion R2 of the interconnect 47a in the opening P of the passivation insulator 48.

In the present embodiment, a total thickness of the insulators 61 and 62 is larger than a thickness of the interconnect layer 46 and smaller than a thickness of the interconnect layer 47 (a thickness of the portion R2). Note that the total thickness of the insulators 61 and 62 is closer to the thickness of the interconnect layer 47 than to the thickness of the interconnect layer 46. Thus, a difference between the thickness of the interconnect layer 47 and the total thickness of the insulators 61 and 62 is smaller than a difference between the total thickness of the insulators 61 and 62 and the thickness of the interconnect layer 46. In contrast, a difference between the thickness of the interconnect layer 47 and the total thickness of the insulators 61 and 62 is larger than a difference between the total thickness of the insulators 61 and 62 and the thickness of the interconnect layer 46 in the later-described second embodiment.

In the present embodiment, the portion R1, i.e., a portion of the interconnect layer 47, is embedded in the opening of the inter layer dielectric 12b. FIG. 7 illustrates a region VA where the opening is formed in the inter layer dielectric 12b. The region VA will be described later in detail.

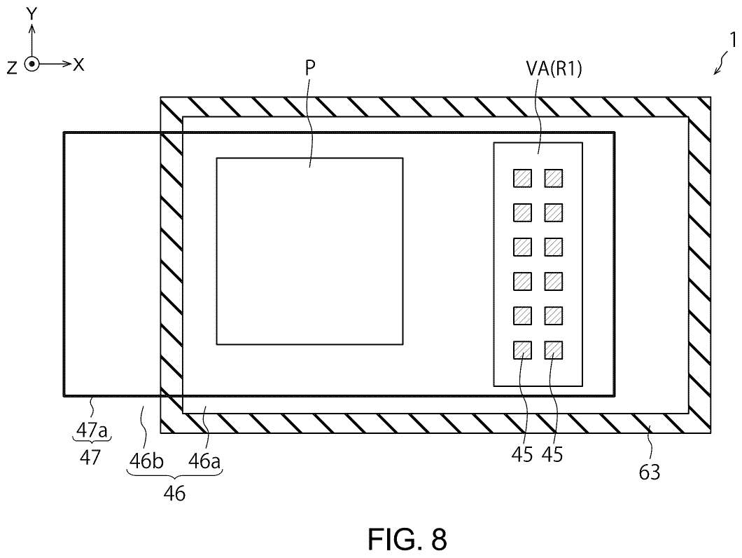

FIG. 8 is a plan view illustrating the structure of the semiconductor device of the first embodiment.

FIG. 8 illustrates an example of a planar structure of the semiconductor device illustrated in FIG. 7. FIG. 8 illustrates the plurality of via plugs 45, the interconnect layer 47 (the interconnect 47a), the insulator 63, the opening P, the region VA, and the like.

In FIG. 8, the insulator 63 has a ring shape in plan view. This causes the interconnect layer 46 to be separated into the interconnect 46a located inside the ring of the insulator 63 and the interconnect 46b located outside the ring of the insulator 63. In this case, the interconnect 46c illustrated in FIG. 7 is a portion of the interconnect 46b. In FIG. 8, the opening P and the region VA are located inside the ring of the insulator 63 in plan view. The region VA corresponds to the portion R1 of the interconnect 47a as described above.

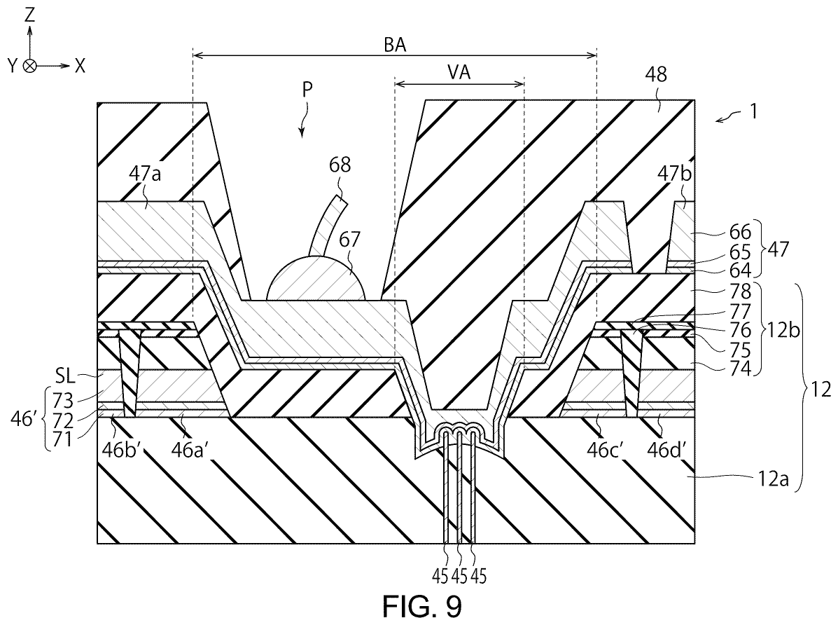

FIG. 9 is a cross-sectional view illustrating a structure of a semiconductor device of a comparative example of the first embodiment.

The semiconductor device of the present comparative example (FIG. 9) has a substantially similar structure to that of the semiconductor device of the first embodiment (FIG. 7). Note that the semiconductor device of the present comparative example includes an interconnect layer 46′ in place of the interconnect layer 46.

The interconnect layer 46′ includes an interconnect 46a′, an interconnect 46b′, an interconnect 46c′, and an interconnect 46d′. The interconnects 46a′ to 46d′ are all formed on the inter layer dielectric 12a and not on the via plugs 45. The interconnect 46b′ serves as the source line SL as the interconnect 46b. The interconnect layer 46′ includes a semiconductor layer 71, a semiconductor layer 72, and a semiconductor layer 73 formed in sequence on the inter layer dielectric 12a. The interconnect 46c′ may be a portion of the interconnect 46a′ and the interconnect 46d′ may be a portion of the interconnect 46b′.

The inter layer dielectric 12b of the present comparative example includes an insulator 74, an insulator 75, an insulator 76, an insulator 77, and an insulator 78. The insulator 74 is formed on the interconnect layer 46′. The insulator 75 is formed on the insulator 74. The insulator 76 penetrates the interconnect layer 46′, the insulator 74, and the insulator 75. The insulator 77 is formed on the insulators 75 and 76. The insulator 78 is formed on the insulator 77 and the inter layer dielectric 12a.

The interconnect layer 47 of the present comparative example includes the interconnect 47a and the interconnect 47b as the interconnect layer 47 of the first embodiment. Note that the interconnect 47a of the present comparative example is disposed, inside the insulator 78, on the via plugs 45, the inter layer dielectric 12a, and the insulator 78 and disposed, outside the insulator 78, on the insulator 78. The interconnect 47a of the present comparative example is thus in contact with not the interconnect layer 46′ but the via plugs 45.

In the present comparative example, a total thickness of the insulators 74, 75, 77, and 78 is larger than a thickness of the interconnect layer 46′. Meanwhile, the total thickness of the insulators 74, 75, 77, and 78 may be smaller than a thickness of the interconnect layer 47 or may be larger than the thickness of the interconnect layer 47. The total thickness of the insulators 74, 75, 77, and 78 of the present comparative example corresponds to the total thickness of the insulators 61 and 62 of the first embodiment.

In the present comparative example, a portion of the interconnect layer 47 is embedded in an opening formed in the interconnect layer 46′ and the insulators 74 to 77. FIG. 9 illustrates a region BA where the opening is formed in the interconnect layer 46′ and the insulators 74 to 77.

In addition, in the present comparative example, a portion of the interconnect layer 47 is embedded in an opening formed in the insulator 78. FIG. 9 illustrates a region VA where the opening is formed in the insulator 78. The interconnect layer 47 in the region VA illustrated in FIG. 9 functions as a via plug as the interconnect layer 47 (the portion R1) in the region VA illustrated in FIG. 7.

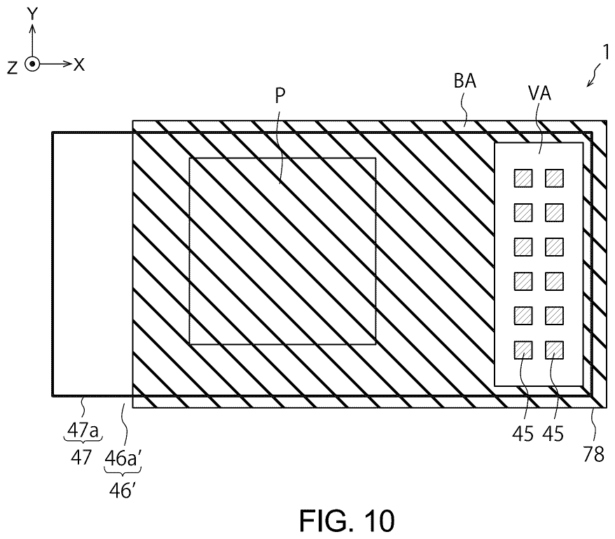

FIG. 10 is a plan view illustrating the structure of the semiconductor device of the comparative example of the first embodiment.

FIG. 10 illustrates an example of a planar structure of the semiconductor device illustrated in FIG. 9. FIG. 9 illustrates the plurality of via plugs 45, the interconnect layer 47 (the interconnect 47a), the insulator 78, the opening P, the region BA, the region VA, and the like.

In FIG. 10, a shape of the insulator 78 defines the region BA and the region VA. For example, the region BA is defined by an interface between a side face of the insulator 78 and a side face of the interconnect 46a′ and the region VA is defined by an interface between the side face of the insulator 78 and a side face of the interconnect 47a. In FIG. 10, the interconnect 46c′ illustrated in FIG. 9 is a portion of the interconnect 46a′.

Here, the first embodiment (FIG. 7) and the comparative example (FIG. 9) are compared.

The interconnect layer 46′ of the present comparative example is formed of the semiconductor layers 71 to 73. It is usually unfavorable that an interconnect of a semiconductor layer is formed directly on a via plug of a metal layer. Accordingly, the opening is formed in the region BA of the interconnect layer 46′ to remove the interconnect layer 46′ from tops of the via plugs 45 in the present comparative example. In addition, the opening is formed in the region VA of the insulator 78 and the interconnect layer 47 is embedded in the opening in the present comparative example. This causes the interconnect 47a of the present comparative example to be formed directly on the via plugs 45.

As a result, the upper face of the interconnect 47a of the present comparative example has not only a step near an outer periphery of the region BA but also a step near an outer periphery of the region VA. In this case, there is a possibility that EM deterioration of the interconnect 47a is caused due to the steps. Further, there is another possibility that the steps of the interconnect 47a increase a Z-directional dimension of the semiconductor device, which becomes an obstacle to downsizing the semiconductor device.

In contrast, the interconnect layer 46 of the present embodiment is formed of the metal layer. As a result, it is not necessary to form, in the interconnect layer 46, an opening corresponding to the opening of the region BA of the interconnect layer 46′. Thus, the interconnect 46a is formed on the via plugs 45 and the interconnect 47a is formed on the interconnect 46a in the present embodiment.

As a result, the upper face of the interconnect 47a of the present embodiment has a step only near the outer periphery of the region VA. This makes it possible to reduce the possibility that EM deterioration of the interconnect 47a is caused due to the step. Further, it becomes possible to reduce the Z-directional dimension of the semiconductor device and, consequently, downsize the semiconductor device. The present embodiment thus allows the interconnect 47a to have a favorable shape.

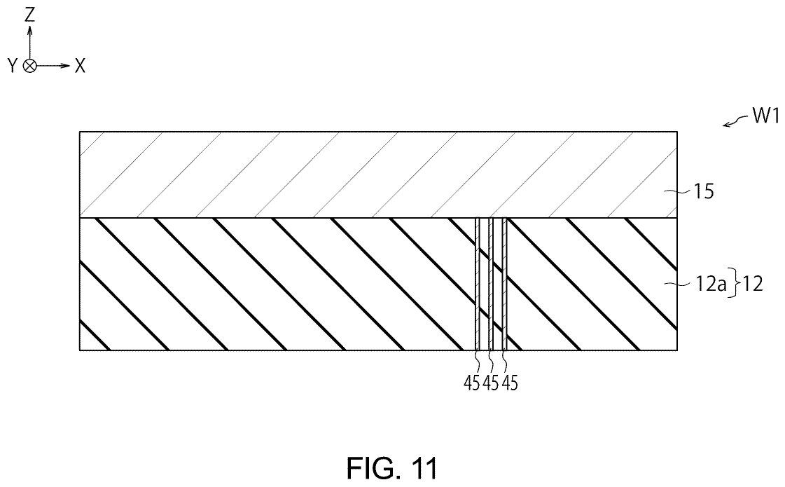

FIGS. 11 to 16 are cross-sectional views illustrating the method of manufacturing the semiconductor device of the first embodiment.

FIG. 11 illustrates the array wafer W1 immediately after bonded to the circuit wafer W2 as FIG. 4. In FIG. 11, the substrate 15 is disposed on the inter layer dielectric 12a and the via plugs 45.

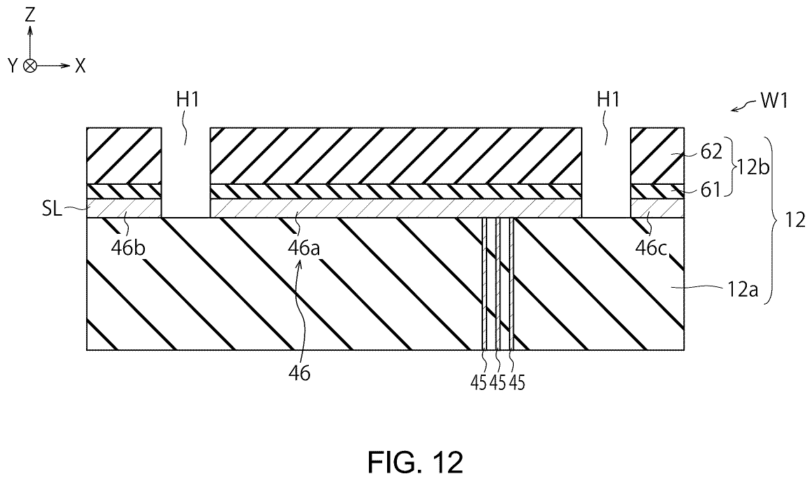

First, the substrate 15 is removed by CMP or wet etching (FIG. 12). As a result, the inter layer dielectric 12a and the via plugs 45 are exposed. Next, the interconnect layer 46, the insulator 61, and the insulator 62 are formed in sequence on the inter layer dielectric 12a and the via plugs 45 (FIG. 12). Next, an opening H1 penetrating the insulator 62, the insulator 61, and the interconnect layer 46 is formed by lithography and RIE (Reactive Ion Etching) (FIG. 12). As a result, the interconnects 46a to 46c are formed from the interconnect layer 46. The interconnect 46a is formed on the via plugs 45 to be in contact with the via plugs 45.

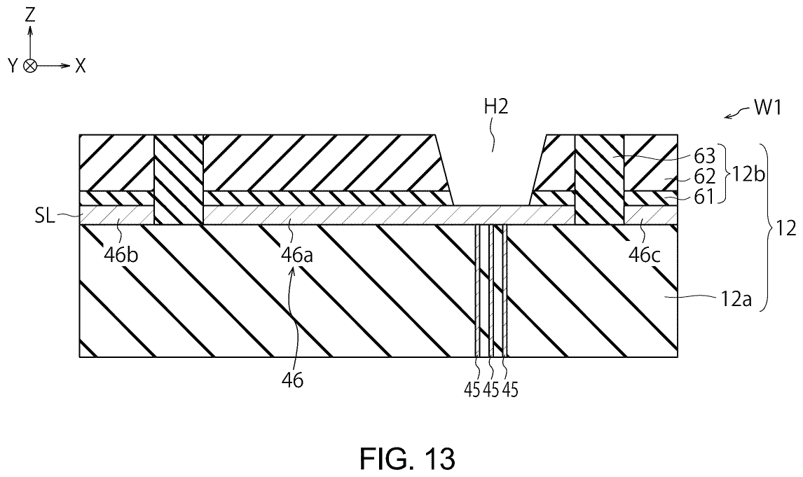

Next, the insulator 63 is formed in the opening H1 (FIG. 13). As a result, the inter layer dielectric 12b including the insulators 61 to 63 is formed. Next, an opening H2 penetrating the insulators 62 and 61 is formed by lithography and RIE (FIG. 13). The opening H2 of the present embodiment is formed above the via plugs 45.

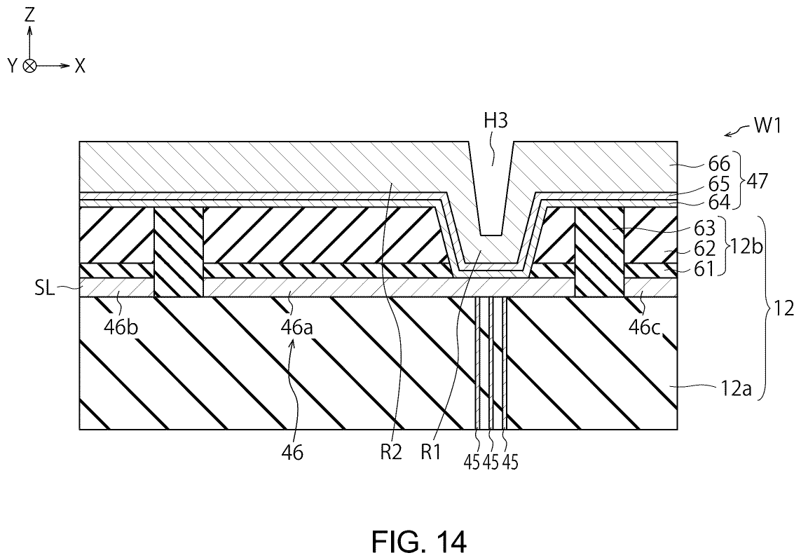

Next, the lower barrier metal layer 64, the upper barrier metal layer 65, and the interconnect material layer 66 are formed in sequence on the inter layer dielectric 12b and the interconnect layer 46 (FIG. 14). As a result, the interconnect layer 47 including the portions R1 and R2 is formed. The portion R1 is formed, inside the opening H2, on the interconnect 46a to be in contact with the interconnect 46a. The portion R2 is formed on the inter layer dielectric 12b outside the opening H2. The opening H2 is used as a via hole where the portion R1 is embedded. The portion R1 functions as a via plug. FIG. 14 further illustrates a concave portion H3 formed on the portion R1 in the interconnect layer 47.

The portion R1 and the portion R2 of the present embodiment both include the lower barrier metal layer 64, the upper barrier metal layer 65, and the interconnect material layer 66. Accordingly, the portion R1 and the portion R2 of the present embodiment are simultaneously formed in the process in FIG. 14.

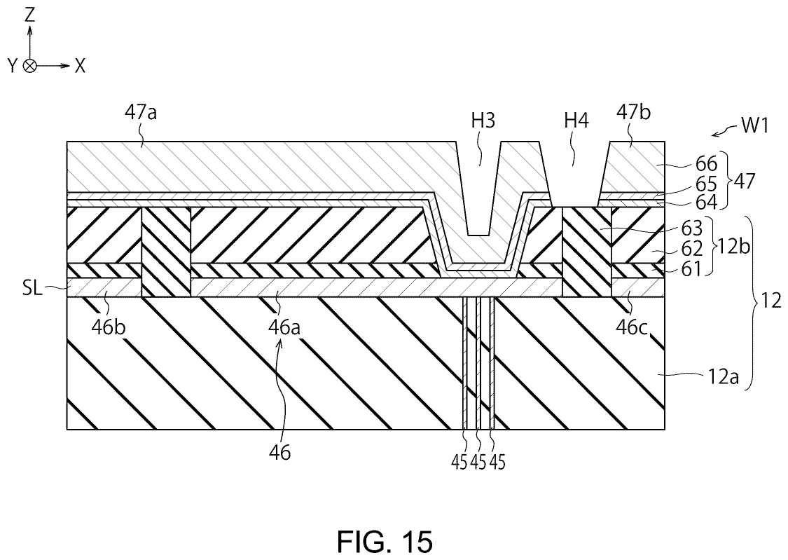

Next, an opening H4 penetrating the interconnect layer 47 is formed by lithography and RIE (FIG. 15). As a result, the interconnects 47a and 47b are formed from the interconnect layer 47. The interconnect 47a is formed to include the portions R1 and R2.

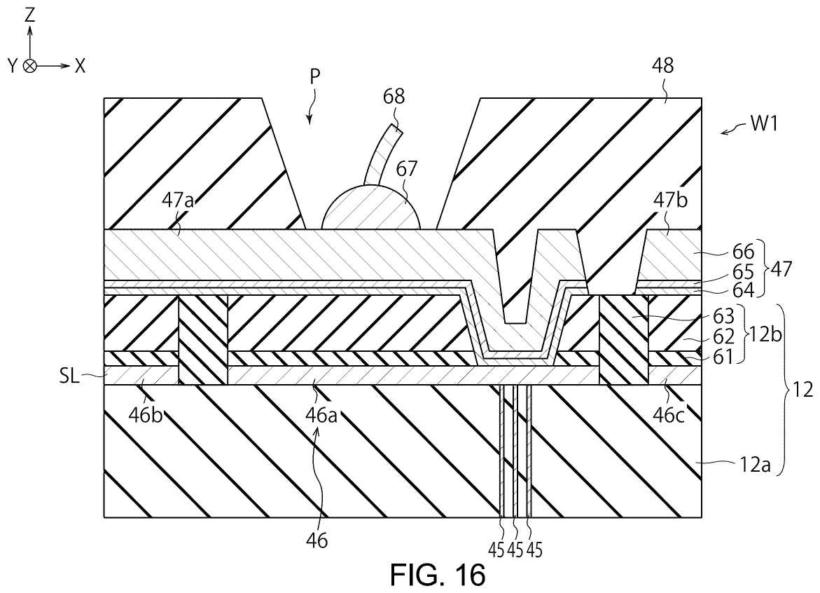

Next, the passivation insulator 48 is formed on the interconnect layer 47 and the opening P is formed in the passivation insulator 48 (FIG. 16). The passivation insulator 48 is also formed in the concave portion H3 and the opening H4. Next, the interconnect 47a and the bonding wire 68 in the opening P are electrically connected by the solder 67 (FIG. 16). The semiconductor device of the present embodiment is manufactured in this manner.

As in the foregoing, the interconnect 46a, not the interconnect 47a, is formed on the via plugs 45 and the interconnect 47a is formed on the interconnect 46a in the present embodiment. Therefore, the present embodiment allows the interconnect 47a to have a favorable shape. For example, it is possible to form the interconnect 47a without forming a step attributed to the region BA.

### Second Embodiment

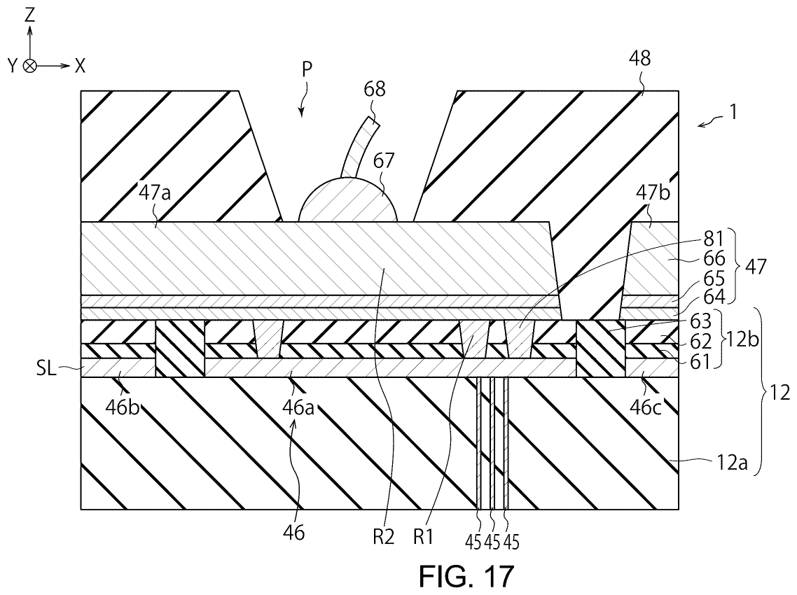

FIG. 17 is a cross-sectional view illustrating a structure of a semiconductor device of a second embodiment.

The semiconductor device of the present embodiment (FIG. 17) has a substantially similar structure to that of the semiconductor device of the first embodiment (FIG. 7). Note that the interconnect layer 47 of the present embodiment includes the lower barrier metal layer 64, the upper barrier metal layer 65, the interconnect material layer 66, and a metal layer 81. The metal layer 81 is, for example, an Al layer.

The interconnect layer 47 of the present embodiment includes the interconnect 47a and the interconnect 47b as the interconnect layer 47 of the first embodiment. In addition, the interconnect 47a of the present embodiment includes a plurality of portions R1 formed on the interconnect 46a inside the inter layer dielectric 12b and the portion R2 formed on the inter layer dielectric 12b outside the inter layer dielectric 12b.

The portions R1 and the portion R2 of the interconnect 47a include different interconnect materials and are formed in sequence in the present embodiment. Specifically, the portions R1 include the metal layer 81 and the portion R2 includes the lower barrier metal layer 64, the upper barrier metal layer 65, and the interconnect material layer 66. The portions R1 are formed by forming the metal layer 81 in the inter layer dielectric 12b. The portion R2 is formed by forming the lower barrier metal layer 64, the upper barrier metal layer 65, and the interconnect material layer 66 in sequence on the inter layer dielectric 12b and the metal layer 81 after the formation of the portions R1.

The upper face of the interconnect 47a of the first embodiment has the step near the outer periphery of the region VA, whereas the upper face of the interconnect 47a of the present embodiment does not have such a step. This is because the portions R1 of the present embodiment are formed from the metal layer 81 before the portion R2 instead of being formed from the lower barrier metal layer 64, the upper barrier metal layer 65, and the interconnect material layer 66 at the same time as the portion R2. Therefore, the present embodiment makes it possible to further reduce the possibility that EM deterioration of the interconnect 47a is caused due to a step.

In the present embodiment, a total thickness of the insulators 61 and 62 is larger than a thickness of the interconnect layer 46 and smaller than a thickness of the interconnect layer 47 (a thickness of the portion R2) as in the first embodiment. Note that, unlike in the first embodiment, the total thickness of the insulators 61 and 62 of the present embodiment is closer to the thickness of the interconnect layer 46 than to the thickness of the interconnect layer 47. A difference between the thickness of the interconnect layer 47 and the total thickness of the insulators 61 and 62 is larger than a difference between the total thickness of the insulators 61 and 62 and the thickness of the interconnect layer 46.

In other words, the total thickness of the insulators 61 and 62 of the first embodiment is increased and the total thickness of the insulators 61 and 62 of the present embodiment is reduced. Therefore, the present embodiment makes it possible to further reduce the Z-directional dimension of the semiconductor device and further downsize the semiconductor device. While it is necessary to increase the total thickness of the insulators 74, 75, 77, and 78 in order to ensure a pressure resistance between the interconnect layer 46′ and the interconnect layer 47 in the comparative example, the present embodiment eliminates such a necessity. This is also the reason why the total thickness of the insulators 61 and 62 of the present embodiment is allowed to be reduced.

The portions R1 of the present embodiment are not only small in Z-directional dimension but also small in area of planar shape. In this case, it is necessary to form a small concave portion in the inter layer dielectric 12b and form the metal layer 81 in the small concave portion. The concave portion is not only small in Z-directional dimension but also small in area of planar shape, which makes an aspect ratio high. It is difficult to form the metal layer 81 in such a concave portion. Accordingly, the metal layer 81 of the present embodiment is formed by pouring a molten metal (for example, aluminum) into the concave portion and hardening the poured metal. This makes it possible to favorably form the metal layer 81 in such a concave portion.

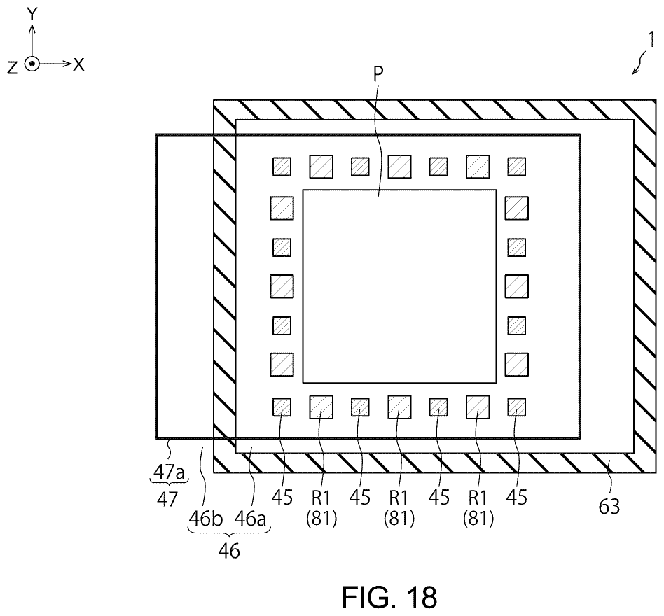

FIG. 18 is a plan view illustrating the structure of the semiconductor device of the second embodiment.

FIG. 18 illustrates an example of a planar structure of the semiconductor device illustrated in FIG. 17. FIG. 18 illustrates the plurality of via plugs 45, the interconnect layer 47 (the interconnect 47a), the insulator 63, the opening P, and the like. FIG. 18 further illustrates a plurality of portions R1 of the interconnect 47a. The portions R1 each include the metal layer 81.

The insulator 63 also has a ring shape in plan view in FIG. 18 as in FIG. 8. This causes the interconnect layer 46 to be separated into the interconnect 46a located inside the ring of the insulator 63 and the interconnect 46b located outside the ring of the insulator 63. In this case, the interconnect 46c illustrated in FIG. 17 is a portion of the interconnect 46b. In FIG. 18, the opening P, the portions R1, and the via plugs 45 are located inside the ring of the insulator 63 in plan view.

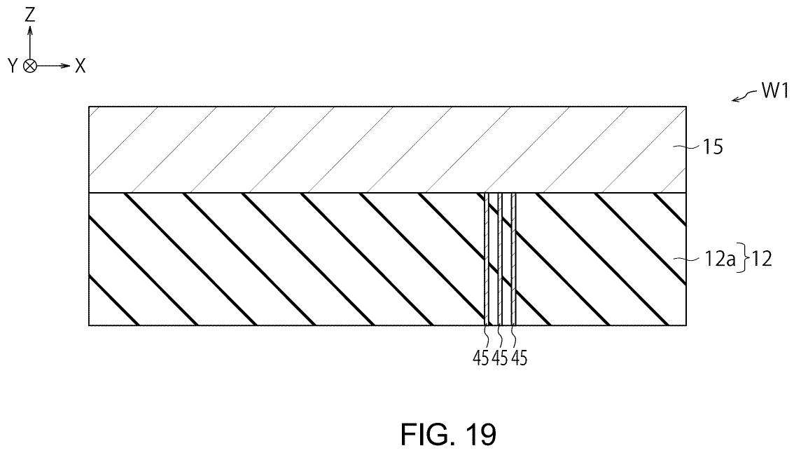

FIGS. 19 to 24 are cross-sectional views illustrating a method of manufacturing the semiconductor device of the second embodiment.

FIG. 19 illustrates the array wafer W1 immediately after bonded to the circuit wafer W2 as FIG. 4 and FIG. 11. In FIG. 19, the substrate 15 is disposed on the inter layer dielectric 12a and the via plugs 45.

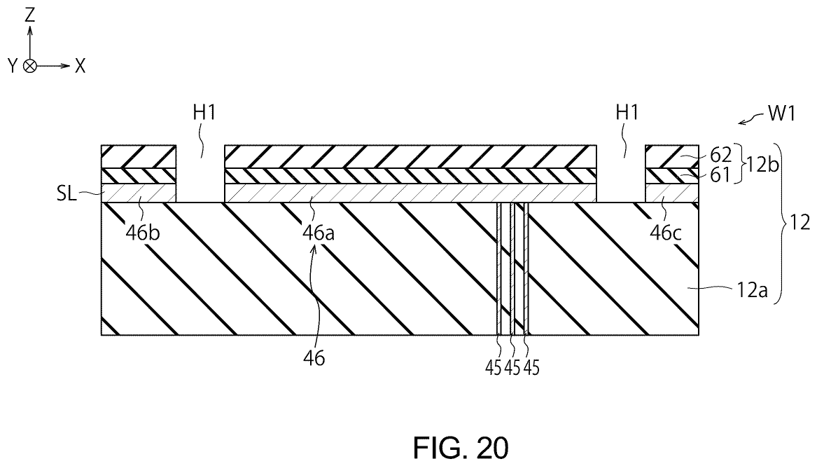

First, the substrate 15 is removed by CMP or wet etching (FIG. 20). As a result, the inter layer dielectric 12a and the via plugs 45 are exposed. Next, the interconnect layer 46, the insulator 61, and the insulator 62 are formed in sequence on the inter layer dielectric 12a and the via plugs 45 (FIG. 20). Next, an opening H1 penetrating the insulator 62, the insulator 61, and the interconnect layer 46 is formed by lithography and RIE (FIG. 20). As a result, the interconnects 46a to 46c are formed from the interconnect layer 46. The interconnect 46a is formed on the via plugs 45 to be in contact with the via plugs 45.

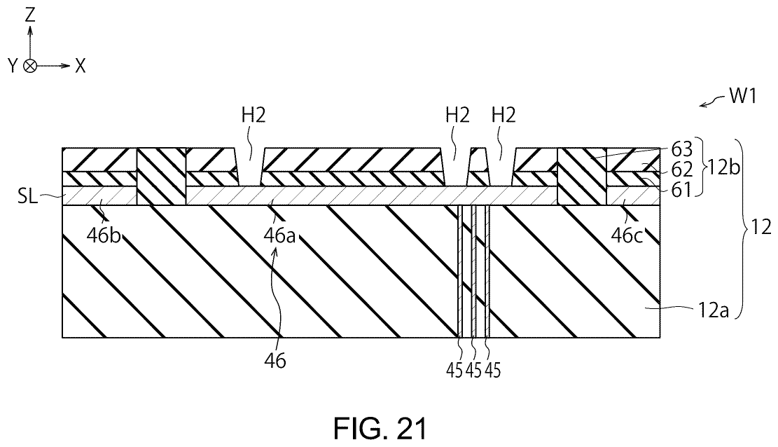

Next, the insulator 63 is formed in the opening H1 (FIG. 21). As a result, the inter layer dielectric 12b including the insulators 61 to 63 is formed. Next, a plurality of openings (concave portions) H2 penetrating the insulators 62 and 61 are formed by lithography and RIE (FIG. 21). The openings H2 are examples of a first concave portion.

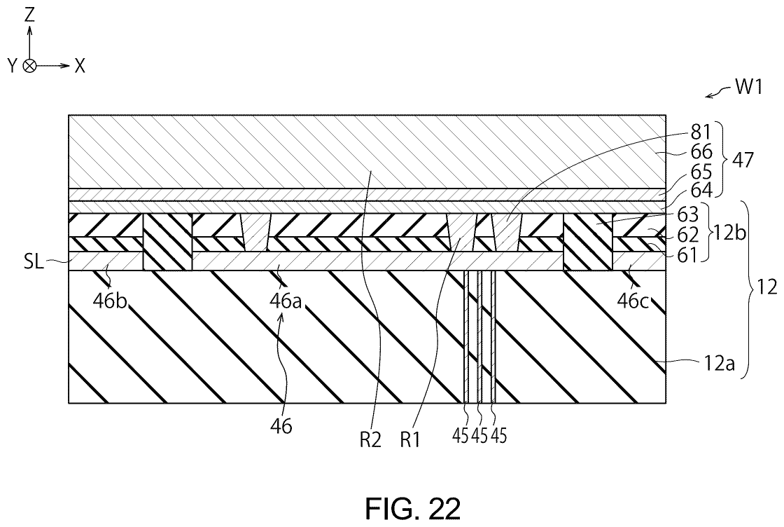

Next, the metal layer 81 is formed in the openings H2 (FIG. 22). As a result, the plurality of portions R1 are formed in the openings H2. The portions R1 are each formed, in the corresponding opening H2, on the interconnect 46a to be in contact with the interconnect 46a. The metal layer 81 of the present embodiment is formed by pouring a molten metal into the concave portions and hardening the poured metal.

Next, the lower barrier metal layer 64, the upper barrier metal layer 65, and the interconnect material layer 66 are formed in sequence on the inter layer dielectric 12b and the metal layer 81 (FIG. 22). As a result, the interconnect layer 47 including the portions R1 and R2 is formed. The portion R2 is formed on the inter layer dielectric 12b and the metal layer 81 outside the openings H2.

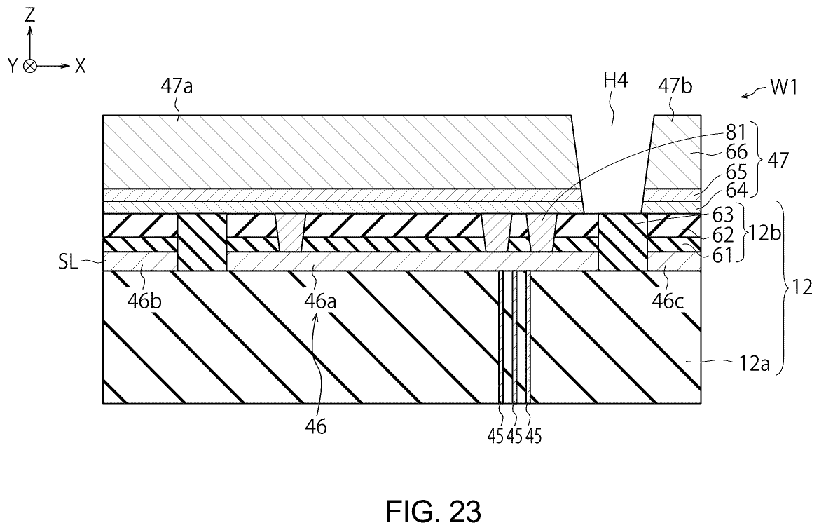

Next, an opening H4 penetrating the interconnect layer 47 is formed by lithography and RIE (FIG. 23). As a result, the interconnects 47a and 47b are formed from the interconnect layer 47. The interconnect 47a is formed to include the portions R1 and R2.

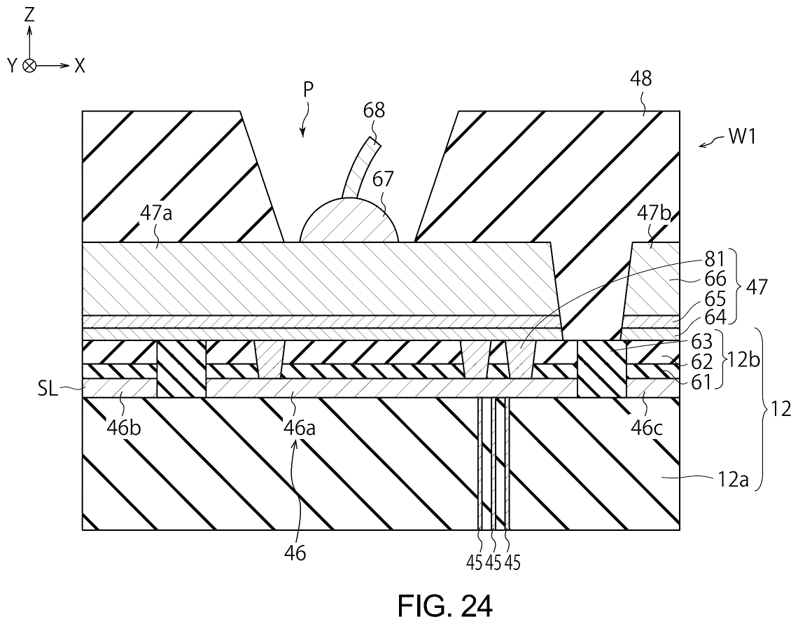

Next, the passivation insulator 48 is formed on the interconnect layer 47 and the opening P is formed in the passivation insulator 48 (FIG. 24). The passivation insulator 48 is also formed in the opening H4. Next, the interconnect 47a and the bonding wire 68 in the opening P are electrically connected by the solder 67 (FIG. 24). The semiconductor device of the present embodiment is manufactured in this manner.

As in the foregoing, the interconnect 46a, not the interconnect 47a, is formed on the via plugs 45 and the interconnect 47a is formed on the interconnect 46a in the present embodiment. Therefore, the present embodiment allows the interconnect 47a to have a favorable shape. For example, it is possible to form the interconnect 47a without forming steps attributed to the regions BA and VA.

### Third Embodiment

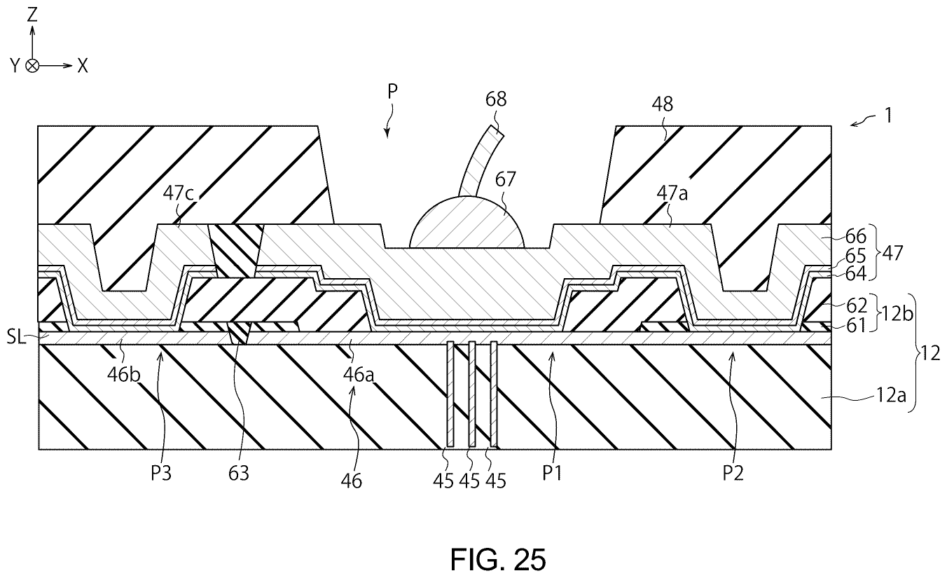

FIG. 25 is a cross-sectional view illustrating a structure of a semiconductor device of a third embodiment.

The semiconductor device of the present embodiment (FIG. 25) has a substantially similar structure to that of the semiconductor device of the first embodiment (FIG. 7). Note that the interconnect layer 47 of the present embodiment includes the interconnect 47a and an interconnect 47c. The interconnect 47a and the interconnect 47c are separated from each other by the passivation insulator 48. In the present embodiment, the interconnect 47a is in contact with the interconnect 46a at a plurality of places labeled with reference signs P1 and P2 and the interconnect 47c is in contact with the interconnect 46b at a place labeled with a reference sign P3. A portion of the interconnect 47c is an example of a fourth portion. Hereinafter, regions labeled with the reference signs P1, P2, and P3 are referred to as “regions P1, P2, and P3”, respectively.

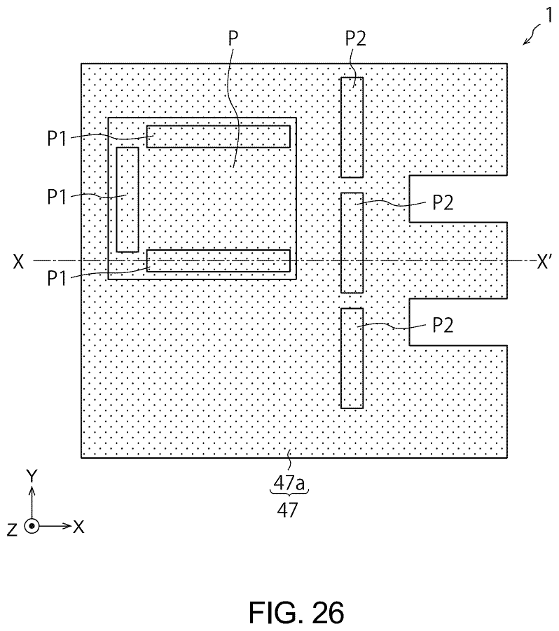

FIG. 26 is a plan view illustrating the structure of the semiconductor device of the third embodiment.

FIG. 26 illustrates an example of a planar shape of the interconnect 47a. FIG. 25 illustrates an XZ cross section along an X-X′ line illustrated in FIG. 26. The interconnect 47a illustrated in FIG. 26 is in contact with the interconnect 46a at three regions P1 located below the opening P of the passivation insulator 48 and in contact with the interconnect 46a at three regions P2 located in the other place. FIG. 25 illustrates, by way of example, one of the regions P1 and one of the regions P2.

The regions P1 each have a rectangular shape extending in the X direction or the Y direction. In the present embodiment, the plurality of via plugs 45 are disposed below each of the regions P1. Meanwhile, the regions P2 each have a rectangular shape extending in the Y direction. In the present embodiment, the plurality of regions P2 are disposed on the same straight line extending in the Y direction. The interconnect 47a of the present embodiment includes a main portion and a plurality of projecting portions projecting in the X direction from the main portion. The main portion includes the regions P1 and P2.

The semiconductor device of the present embodiment is manufacturable by the processes illustrated in FIGS. 11 to 16 as the semiconductor device of the first embodiment. Note that in manufacturing the semiconductor device of the present embodiment, a plurality of openings H2 are formed at places corresponding to the respective regions P1 to P3 in the process illustrated in FIG. 13.

In the present embodiment, the interconnect layer 47 is caused to be in contact with the interconnect layer 46 at the regions P1 to P3, which makes it possible to more favorably control, for example, a potential of the interconnect layer 46 through the interconnect layer 47.

### Fourth Embodiment

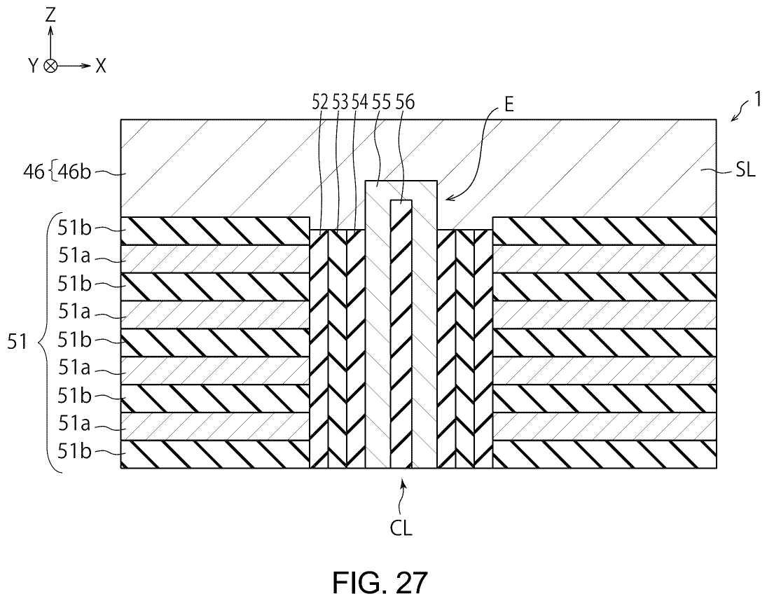

FIG. 27 is a cross-sectional view illustrating a structure of a semiconductor device of a fourth embodiment.

The semiconductor device of the present embodiment has a similar structure to that of the semiconductor device of the first embodiment. The semiconductor device of the present embodiment further includes the structure illustrated in FIG. 27. FIG. 27 illustrates the stacked film 51, the columnar portion CL provided in the stacked film 51, and the interconnect 46b (the source line SL) provided on the columnar portion CL.

In the columnar portion CL in FIG. 27, an upper end portion E of the channel semiconductor layer 55 projects in the +Z direction with respect to upper faces of the block insulator 52, the charge storage layer 53, and the tunnel insulator 54. The interconnect 46b is provided on the channel semiconductor layer 55 to be in contact with the channel semiconductor layer 55 at the upper end portion E. In the present embodiment, the metal layer, or interconnect 46b, is electrically connected to the channel semiconductor layer 55 by Schottky barrier junction. The Schottky barrier junction will be described later in detail.

The channel semiconductor layer 55 of the present embodiment includes neither p-type impurity atoms nor n-type impurity atoms but, alternatively, at least the upper end portion E may include p-type impurity atoms or n-type impurity atoms. This makes it possible to electrically connect the metal layer, or interconnect 46b, to the channel semiconductor layer 55 by non-Schottky barrier junction.

The semiconductor device of the present embodiment is manufacturable by the processes illustrated in FIGS. 11 to 16 as the semiconductor device of the first embodiment. Note that in manufacturing the semiconductor device of the present embodiment, the interconnect 46b is formed on the channel semiconductor layer 55 of each columnar portion CL in the process illustrated in FIG. 12.

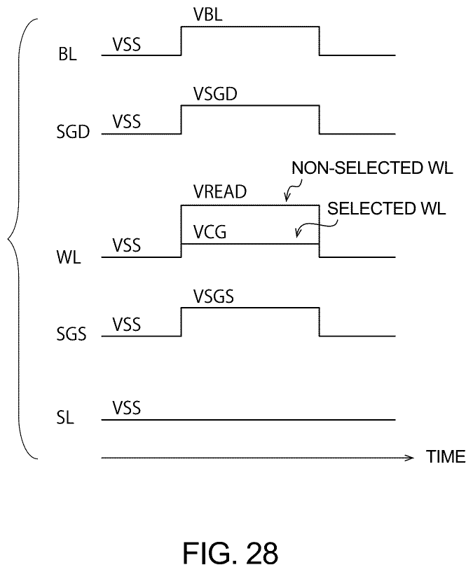

FIG. 28 is a timing chart illustrating an operation example of the semiconductor device of the fourth embodiment.

FIG. 28 illustrates an example of a reading operation of the semiconductor device of the present embodiment. FIG. 28 indicates voltages of interconnects such as the bit line BL, the drain-side selective line SGD, a selected word line WL, a non-selected word line WL, the source-side selective line SGS, and the source line SL.

Before the start of the reading operation, the voltages of the bit line BL, the drain-side selective line SGD, the selected word line WL, the non-selected word line WL, the source-side selective line SGS, and the source line SL are equal to, for example, a ground voltage VSS. When the reading operation is started, a voltage VBL is applied to the bit line BL, a voltage VSGD is applied to the drain-side selective line SGD, a voltage VCG is applied to the selected word line WL, a voltage VREAD is applied to the non-selected word line WL, and a voltage VSGS is applied to the source-side selective line SGS.

The voltage VBL is a voltage higher than the ground voltage VSS. The voltage VSGD is a voltage that causes the drain-side selective transistor in a selected block to be turned on during the reading operation. The voltage VCG is a reading voltage for determining data stored in the cell transistor. The cell transistor applied with the voltage VCG goes into an ON state or an OFF state in accordance with a threshold voltage set for each value of data to be stored. The voltage VREAD is a voltage that causes the cell transistor to be turned on irrespective of the value of data to be stored. The voltage VSGS is a voltage that causes the source-side selective transistor in the selected block to be turned on during the reading operation.

In response to the application of these voltages to the interconnects illustrated in FIG. 28, a channel is formed in the channel semiconductor layer 55 of a NAND string of the semiconductor device of the present embodiment. A channel current then flows in accordance with a threshold voltage of the cell transistor connected to the selected word line WL. In a sense amplifier unit, a voltage of a sense node changes with a state of the NAND string. Subsequently, in response to a sequencer asserting a control signal, the sense amplifier unit determines the threshold voltage of the cell transistor on the basis of the voltage of the sense node. The semiconductor device of the present embodiment causes reading data to be confirmed on the basis of a determination result of the threshold voltage. When the reading operation is terminated, the respective states of the interconnects are restored to states before the start of the reading operation.

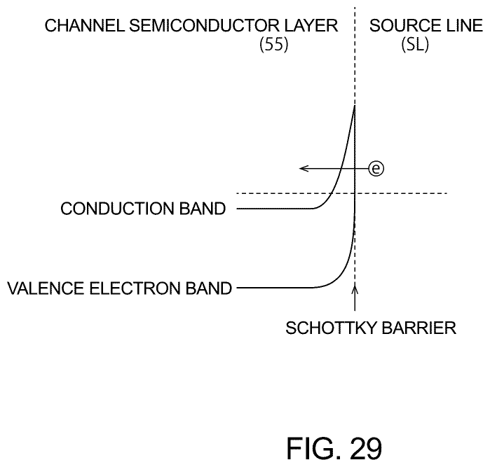

FIG. 29 is a graph for explaining an operation of the semiconductor device of the fourth embodiment.

FIG. 29 illustrates an example of a band structure in the NAND string during the reading operation. In FIG. 29, the vertical axis represents energy and the horizontal axis represents a region from a channel of the NAND string to the source line SL. As illustrated in FIG. 29, a Schottky barrier is formed between the channel of the NAND string and the source line SL.

During the reading operation, the voltage VREAD is applied to the non-selected word line WL, the voltage VSGS is applied to the source-side selective line SGS, and the voltage VSGD is applied to the drain-side selective line SGD, which lowers an energy in a conduction band. This reduces a thickness of the Schottky barrier formed between the channel and the source line SL. Then, electrons (“e” seen in FIG. 29) are supplied from the source line SL toward the channel of a NAND string NS. It means that for the reading operation of the present embodiment, a reverse bias relative to the Schottky barrier junction is applied and a tunnel current directed from the source line SL toward the channel is used.

The present embodiment allows the semiconductor device to operate as a memory even though the metal layer, or interconnect 46b (the source line SL), is formed on the channel semiconductor layer 55.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a first substrate;
a memory cell array including a plurality of first electrode layers that are provided above the first substrate, and are spaced from each other in a first direction, a columnar portion that is provided in the plurality of first electrode layers, extends in the first direction, and includes a charge storage layer and a semiconductor layer, and a first metal layer that is provided above the plurality of first electrode layers, and is electrically connected to an end of the semiconductor layer;
a first plug provided above the first substrate; and
a first interconnect layer provided above the first plug, and electrically connected to the first plug through the first metal layer.

2. The device of claim 1, further comprising a first insulator provided between the first metal layer and the first interconnect layer.

3. The device of claim 2, wherein the first interconnect layer is electrically connected to the first plug through a second plug provided in the first insulator.

4. The device of claim 3, wherein
the first interconnect layer includes a barrier metal layer, and an interconnect material layer provided on the barrier metal layer, and
the barrier metal layer and the interconnect material layer are also included in the second plug.

5. The device of claim 3, wherein
the first interconnect layer includes a barrier metal layer, and an interconnect material layer provided on the barrier metal layer, and
neither the barrier metal layer nor the interconnect material layer is included in the second plug.

6. The device of claim 1, wherein the first metal layer includes:
a first portion provided above the plurality of first electrode layers, and electrically connected to the end of the semiconductor layer, and
a second portion separated from the first portion, and electrically connected to the first plug and the first interconnect layer.

7. The device of claim 6, wherein the first portion is a source line.

8. The device of claim 6, wherein the first portion is provided on the semiconductor layer to be in contact with the semiconductor layer.

9. The device of claim 8, wherein the first portion is electrically connected to the semiconductor layer by Schottky barrier junction.

10. The device of claim 8, wherein the first portion is electrically connected to the semiconductor layer including impurity atoms by non-Schottky barrier junction.

11. The device of claim 1, wherein the first interconnect layer includes a bonding pad.

12. The device of claim 6, wherein the first interconnect layer includes a third portion electrically connected to the second portion at a plurality of places.

13. The device of claim 6, wherein the first interconnect layer further includes a fourth portion electrically connected to the first portion.

14. A method of manufacturing a semiconductor device, comprising:
forming a memory cell array including a plurality of first electrode layers that are provided above a first substrate, are spaced from each other in a first direction, a columnar portion that is provided in the plurality of first electrode layers, extends in the first direction, and including a charge storage layer and a semiconductor layer, and a first metal layer that is provided above the plurality of first electrode layers, and electrically connected to an end of the semiconductor layer;
forming a first plug above the first substrate; and
forming a first interconnect layer provided above the first plug, and electrically connected to the first plug through the first metal layer.

15. The method of claim 14, further comprising forming a first insulator on the first metal layer,
wherein the first interconnect layer is formed on the first insulator.

16. The method of claim 15, wherein the first interconnect layer is electrically connected to the first plug through a second plug provided in the first insulator.

17. The method of claim 16, wherein the first interconnect layer and the second plug are simultaneously formed.

18. The method of claim 16, wherein the first interconnect layer is formed after the second plug is formed.

19. The method of claim 16, the second plug is formed by pouring a molten metal into a first concave portion formed in the first insulator.

20. The method of claim 14, wherein
the plurality of first electrode layers and the columnar portion are formed above a second substrate,
the second substrate is bonded to the first substrate to cause the plurality of first electrode layers and the columnar portion to be disposed above the first substrate, and is removed after bonded to the first substrate, and
the first metal layer is formed above the plurality of first electrode layers after the second substrate is removed.
